(19) United States
(12) Patent Application Publication
(10) Pub. No.: US 2011/0279298 A1
(43) Pub. Date: Nov. 17, 2011

(54) DIGITAL-TO-ANALOG CONVERTER CIRCUIT USING CHARGE SUBTRACTION METHOD AND CHARGE TRANSFER INTERPOLATION METHOD

(75) Inventors: Ji-Hun KIM, Daejeon-si (KR); Yeong-Joon Son, Daejeon-si (KR); Joon-Ho Na, Daejeon-si (KR); Jeong-Yeol Bae, Chungbuk (KR); Sang-Gug Lee, Daejeon-si (KR)

(73) Assignee: SILICON WORKS CO., LTD, Daejeon-si (KR)

(21) Appl. No.: 13/100,596

(22) Filed: May 4, 2011

(30) Foreign Application Priority Data
May 13, 2010 (KR) 10-2010-0044815

(51) Int. Cl. H03M 1/66

(52) U.S. Cl. 341/150

(57) ABSTRACT

A DAC circuit using a charge subtraction method and a change transfer interpolation method includes resistor cells configured to divide a voltage of data of total K bits (=upper M bits+lower N bits) by resistance dividers; a decoder group configured to receive digital data of the M bits and the N bits divided in the resistor cells, process the digital data by the unit of 2 bits, and output respective corresponding voltages; a capacitor group configured to receive the voltages outputted from the decoder group and realize charge charging by a charge subtraction method and charge transferring by a charge transfer interpolation method; and an operational amplifier having a first input terminal which receives a reference voltage and a second input terminal which receives an interpolation voltage corresponding to an amount of charges transferred from the capacitor group, and configured to generate an output voltage.

### BACKGROUND OF THE INVENTION

1. Field of the Invention

The present invention relates to a digital-to-analog converter (hereinafter, referred to as a “DAC”) for a display, and more particularly, to a DAC circuit using a charge subtraction method and a change transfer interpolation method, which can decrease the number of resistors constituting a resistance divider and the number of switches employed in a DAC, thereby reducing the overall area of the DAC.

2. Description of the Related Art

A DAC circuit for a display is a circuit for supplying a precise voltage corresponding to a digital code value, as a final output.

In the conventional art, in order to supply a precise voltage, an R-DAC (resistor-string digital-to-analog converter), which can be realized in an easy manner and uses a precise resistance value, has been mainly used. Currently, as a resolution becomes high, a problem is caused in that it is difficult to realize a high resolution using the conventional R-DAC. This is because, in the case of the R-DAC, resistance values of resistors and the number of switches for selecting the resistors increase in geometrical progressions as the number of bits increases.

In order to cope with these problems, various methods have been adopted. A method most frequently adopted currently in DACs. for a display is to use interpolation.

Methods of using interpolation are generally divided into three methods, that is, a basic method of using resistors, a method of using capacitors and a method of using charges.

FIG. 1a shows a first embodiment of a conventional R-DAC circuit.

Referring to FIG. 1, a conventional R-DAC circuit includes a first resistance divider 110, first selection switches 120, a second resistance divider 130, and second selection switches 140.

If the first resistance divider 110 divides an entire voltage corresponding to, for example, 10 bits, into a value corresponding to M bits, for example, 7 bits, the first selection switches 120 select the voltage divided into the 7 bits.

In a similar way, if the second resistance divider 130 divides the remaining voltage of the entire voltage into a value corresponding to N bits, for example, 3 bits, the second selection switches 140, select the voltage divided into the 3 bits and output the value thereof as a final output voltage Vout.

When considering the method as a whole, advantages are provided in that the numbers of resistors and switches can be decreased while it is possible to output precise voltage values divided into M and N bits as final output voltage values.

However, in such a method, a problem is caused in that, because the resistors of the first resistance divider 110 and the resistors of the second resistance divider 130 should be connected in parallel, the resistance value of the first resistance divider 110 is substantially changed due to presence of the resistors of the second resistance divider 130 used for interpolation, and therefore, a desired voltage is not likely to be precisely outputted.

FIG. 1b shows a second embodiment of a conventional R-DAC circuit.

Referring to FIG. 1b, a second embodiment of a conventional R-DAC circuit includes a first resistance divider 110, first selection switches 120, a buffer unit 125, a second resistance divider 130, and second selection switches 140.

In the second embodiment of a conventional R-DAC circuit, due to the fact that the buffer unit 125 is inserted between the first selection switches 120 and the second resistance divider 130, M bits of the first resistance divider 110 are not influenced by a resistance value of the second resistance divider 130. Thus, it is possible to solve the problem of the first embodiment of a conventional R-DAC circuit caused in that a desired voltage is not likely to be precisely outputted due to a change in the resistance value of the first resistance divider 110 resulting from the parallel connection.

Nevertheless, the second embodiment of a conventional R-DAC circuit suffers from a defect in that a precise voltage value is not likely to be outputted due to an additional areal increase by the buffer unit 125 and an offset voltage induced by the buffer unit 125.

FIG. 2 shows a first embodiment of a conventional RC-DAC (resistor-capacitor digital-to-analog converter) circuit.

Referring to FIG. 2, a first embodiment of a conventional RC-DAC circuit includes a first resistance divider 210, first selection switches 220, a capacitor selecting switch unit 230, and an operational amplifier 240. Hence, the first embodiment of a conventional RC-DAC circuit simultaneously uses resistors and capacitors.

The first resistance divider 210 divides an entire voltage corresponding to, for example, 10 bits, into a value corresponding to M bits, for example, 7 bits, and the capacitor selecting switch unit 230 determines the remaining voltage of the entire voltage, as a value corresponding to N bits, for example, 3 bits, by using a binary code value of a binary capacitor.

Nonetheless, in the first embodiment of a conventional RC-DAC circuit, although advantages are provided in that the numbers of switches can be decreased by numbers corresponding to the M bits and the N bits in a manner similar to the R-DACs shown in FIGS. 1a and 1b, a problem still exists in that, since the binary code value of the N-bit binary capacitor is needed for interpolation, the size of the capacitor substantially increases.

In this regard, because the size of respective capacitors constituting the capacitor selecting switch unit 230 is substantially relevant to the value of an error, capacitors with small capacitance values cannot be used. Thus, when actually designing a circuit, a substantial chip area reduction effect may not be anticipated.

FIG. 3 shows a second embodiment of a conventional RC-DAC circuit.

Referring to FIG. 3, a second embodiment of a conventional

RC-DAC circuit is applied to total 10 bits, and includes a 2-to-4 decoder 321, a first 4-to-16 decoder 323, a second 4-to-16 decoder 325, first, second and third capacitors 331, 333 and 335 for charging and transferring charges for the sake of interpolation, and an operational amplifier 340.

Although the second embodiment of a conventional RC-DAC circuit is similar to the first embodiment of a conventional RC-DAC circuit in that it uses resistors and capacitors, the second embodiment of a conventional RC-DAC circuit is distinguished from the first embodiment of a conventional RC-DAC circuit in that the value of lower N bits is not determined using the binary code value of the binary capacitor but is determined by the first, second and third capacitors 331, 333 and 335 for charging and transferring charges for the sake of interpolation.

Voltage values V₅, V₄ and V₃ divided by resistance dividers (not shown) are not divided into the same value but are divided into respective voltage values in proportion to bit values of the 2-to-4 decoder 321, the first 4-to-16 decoder 323 and the second 4-to-16 decoder 325.

The voltage values V₅, V₄ and V₃ divided by the bit values are respectively stored in the first, second and third capacitors 331, 333 and 335. The charges stored in the first, second and third capacitors 331, 333 and 335 finally gather in the first capacitor 331, and a desired final output voltage value Vout is provided to the output terminal of the operational amplifier 340.

FIG. 4 is a diagram explaining a conventional charge transfer interpolation method.

Referring to FIG. 4, a phase 1 represents a charge charging step of storing charges in respective capacitors 10 and 20. In the phase 1, a voltage V_{MSB} of a most significant bit is stored in the first capacitor 10, and a voltage V_{LSB} of a least significant bit is stored in the second capacitor 20. The first capacitor 10 and the second capacitor 20 are connected with an AC ground part 30.

A phase 2 represents a charge transferring step of transferring the charges stored in the second capacitor 20 to the first capacitor 10. In the phase 2, an AC ground voltage is applied to the second capacitor 20, and the first capacitor 10 and the second capacitor 20 are connected with the AC ground part 30.

A principle in which the conventional charge transfer interpolation method is implemented by the configurations of the phase 1 and the phase 2 will be described below.

In the phase 1, one nodes of both nodes of the first capacitor 10 and the second capacitor 20 are connected to the AC ground part 30. If a desired voltage value V_{MSB} is applied to the other node of the first capacitor 10 and a desired voltage value V_{LSB} is applied to the other node of the second capacitor 20, the charges stored in the first capacitor 10 and the second capacitor 20 are charged with C*V_{MSB} and C*V_{LSB}, respectively, according to an equation of Q=CV.

In the phase 2, the charges stored in the first capacitor 10 and the second capacitor 20 gather in the first capacitor 10 and are then outputted, by which a final output voltage has the value of V_{MSB}+V_{LSB}.

Hereafter, an operational principle for realizing the conventional charge transfer interpolation method will be described with reference to FIGS. 3 and 4.

In the case of the phase 1, when assuming that charges stored in the first, second and third capacitors 331, 333 and 335 by applying a desired interpolated voltage are Q1, Q2 and Q3, respectively, a total stored charge is expressed as in the following Mathematical Equation 1 by formulas Qs=Q1+Q2+Q3 and Q=CV.

Qs=C₁(V₅−V_{OS})+C₂(V₄−V_{L}−V_{OS})+C₃(V₃−V_{L}−V_{OS}) [Mathematical Equation 1]

Here, V_{OS} means an offset voltage which is generated from the operational amplifier 340.

In the case of the phase 2, after all the charges stored in the respective second and third capacitors 333 and 335 are transferred to the first capacitor 331 by connecting the other nodes of the second and third capacitors 333 and 335 with an AC ground part, a final output voltage Vout is generated. When assuming that the amounts of charges transferred to the first, second and third capacitors 331, 333 and 335 are Q1, Q2 and Q3, respectively, a total amount of transferred charges satisfies a formula Qt=Q1+Q2+Q3 and is expressed as in the following Mathematical Equation 2 by the formula Q=CV.

Qt=C₁(Vout−V_{L}V_{OS})+C₂(−V_{Os})+C₃(−V_{OS}) [Mathematical Equation 2]

Here, V_{OS} means an offset voltage which is generated from the operational amplifier 340.

Meanwhile, since the electric charge conservation law satisfies Qs=Qt, the total output voltage Vout is expressed as in the following Mathematical Equation 3.

$$Vout = {V}_{5} + \frac{{C}_{2}}{{C}_{1}} ( {V}_{4} - {V}_{L} ) + \frac{{C}_{3}}{{C}_{1}} ( {V}_{2} - {V}_{L} ) \qquad [ Mathematical Equation 3 ]$$

When assuming that digital code values corresponding to V₅, V₄ and V₃ are D₁, D₂ and D₃, respectively, V₅, V₄ and V₃ are expressed by respective equations given in the following Mathematical Equation 4.

$${V}_{5} = \frac{{V}_{L}}{{2}^{2}} {D}_{1} + {V}_{L} \\ {V}_{4} = \frac{{V}_{DD}}{{2}^{2} \times {2}^{4}} {D}_{2} + {V}_{L} \\ {V}_{3} = \frac{{V}_{DD}}{{2}^{2} \times {2}^{4} \times {2}^{4}} {D}_{3} + {V}_{L} \qquad [ Mathematical Equation 4 ]$$

When C1=C2=C3, the total output voltage is simply expressed in the form of Vout=V₅+(V₄−V_{L})+(V₃−V_{L}). When substituting the Mathematical Equation 4 for the Mathematical Equation 3 and simplifying the Mathematical Equation 3, the total output voltage Vout is expressed as in the following Mathematical Equation 5.

$$Vout = \frac{{V}_{L}}{{2}^{2}} {D}_{1} + \frac{{V}_{DD}}{{2}^{2} \times {2}^{4}} {D}_{2} + \frac{{V}_{DD}}{{2}^{2} \times {2}^{4} \times {2}^{4}} {D}_{3} + {V}_{L} \qquad [ Mathematical Equation 5 ]$$

Referring to the Mathematical Equation 5, it is to be understood that, in the conventional RC-DAC circuit, voltage values corresponding to the digital codes stored in the respective first, second and third capacitors 331, 333 and 335 are inputted, are finally collected in one place and are outputted as an output.

Hereinbelow, degrees to which the areas of circuits are reduced will be considered by simply comparing the numbers of needed switches when the DAC circuits shown in FIGS. 1a through 3 process 10 bits.

In the case of the R-DAC circuits shown in FIGS. 1a and 1b, switches are needed by the number of 2¹⁰=1024. In the case of the RC-DAC circuit shown in FIG. 2, if division is made to upper 7 bits and lower 3 bits, switches are needed by the number of 2⁷+2³=128+8=136. Since values of C, C, 2C, 4C and 8C as values of binary capacitors for 3 bits are needed, an overall size of capacitors actually has a value of 16C.

In the case of the RC-DAC shown in FIG. 3, if interpolation is implemented in the same manner as in FIG. 2, while the number of switches is the same as 136, since values of C, C and C, that is, 3C, are needed, advantages are provided in that an overall size of capacitors is reduced when compared to the second method.

However, in the case of the RC-DAC shown in FIG. 3, because interpolation should be implemented one time for each capacitor, limitations exist in decreasing the number of decoders. Thus, an interpolation method adopting a new scheme is demanded in the art.

### SUMMARY OF THE INVENTION

Accordingly, the present invention has been made in an effort to solve the problems occurring in the related art, and an object of the present invention is to provide a DAC circuit for a display, using a charge subtraction method and a change transfer interpolation method, which can decrease the number of resistors constituting a resistance divider and the number of switches employed in a DAC, thereby reducing the overall area of the DAC.

In order to achieve the above object, according to one aspect of the present invention, there is provided a DAC circuit using a charge subtraction method and a change transfer interpolation method, including: resistor cells configured to divide a voltage of data of total K bits (=upper M bits+lower N bits) by respective resistance dividers; a decoder group configured to receive digital data of the M bits and the N bits divided in the resistor cells, process the digital data by the unit of 2 bits, and output respective corresponding voltages; a capacitor group configured to receive the voltages outputted from the decoder group and realize charge charging by a charge subtraction method and charge transferring by a charge transfer interpolation method; and an operational amplifier having a first input terminal which receives a reference voltage and a second input terminal which receives an interpolation voltage corresponding to an amount of charges transferred from the capacitor group, and configured to generate an output voltage.

### BRIEF DESCRIPTION OF THE DRAWINGS

The above objects, and other features and advantages of the present invention will become more apparent after a reading of the following detailed description taken in conjunction with the drawings, in which:

FIG. 1a shows a first embodiment of a conventional R-DAC circuit;

FIG. 1b shows a second embodiment of a conventional R-DAC circuit;

FIG. 2 shows a first embodiment of a conventional RC-DAC circuit;

FIG. 3 shows a second embodiment of a conventional RC-DAC circuit;

FIG. 4 is a diagram explaining a conventional charge transfer interpolation method;

FIG. 5a shows resistor cells which constitute a DAC circuit for a 10-bit display in accordance with an embodiment of the present invention;

FIG. 5b shows a DAC circuit using a charge subtraction method according to the present invention;

FIG. 6 is a diagram explaining a charge transfer interpolation method using a charge subtraction method according to the present invention;

FIG. 7a is a diagram showing allocation of digital codes to a phase 1 and a phase 2 to allow a charge subtraction method or a charge summation method to be used according to the present invention; and

FIG. 7b shows an example of realizing an MSB code operation and an LSB code operation by applying the charge subtraction method or the charge summation method according to the present invention to a 4-bit decoder.

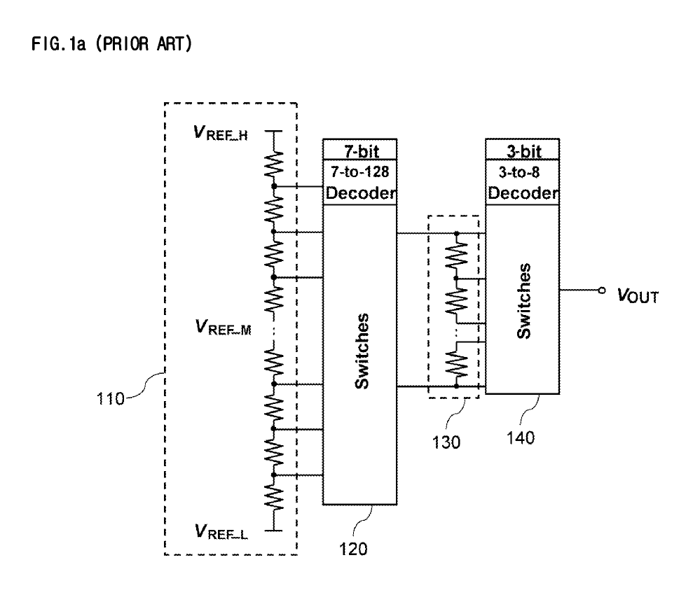

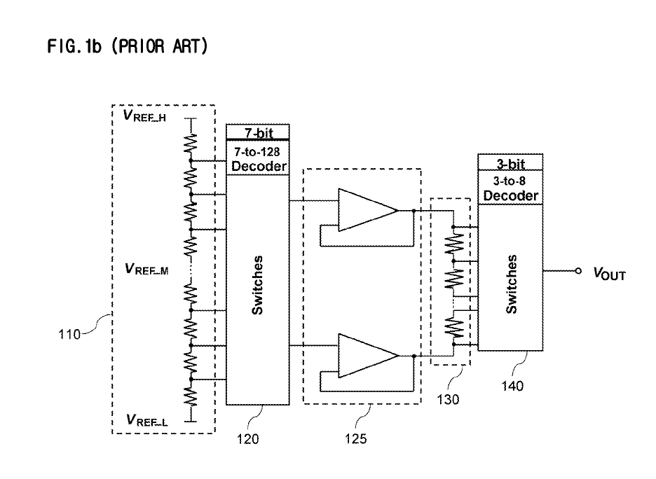

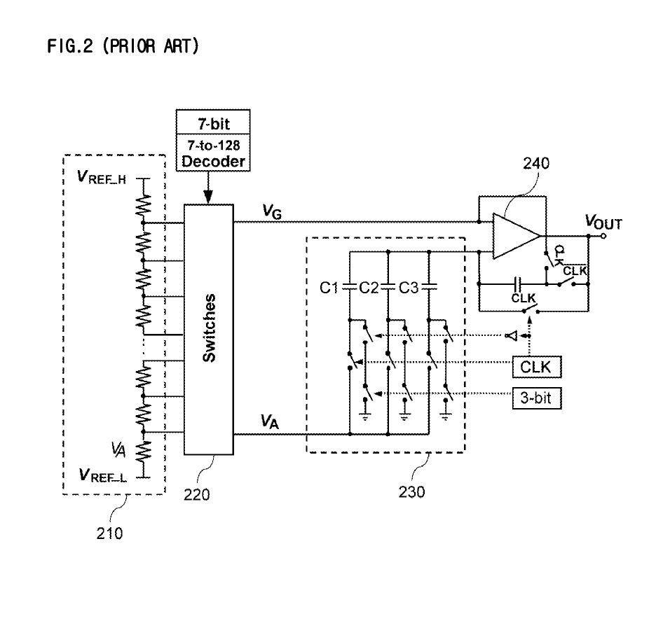

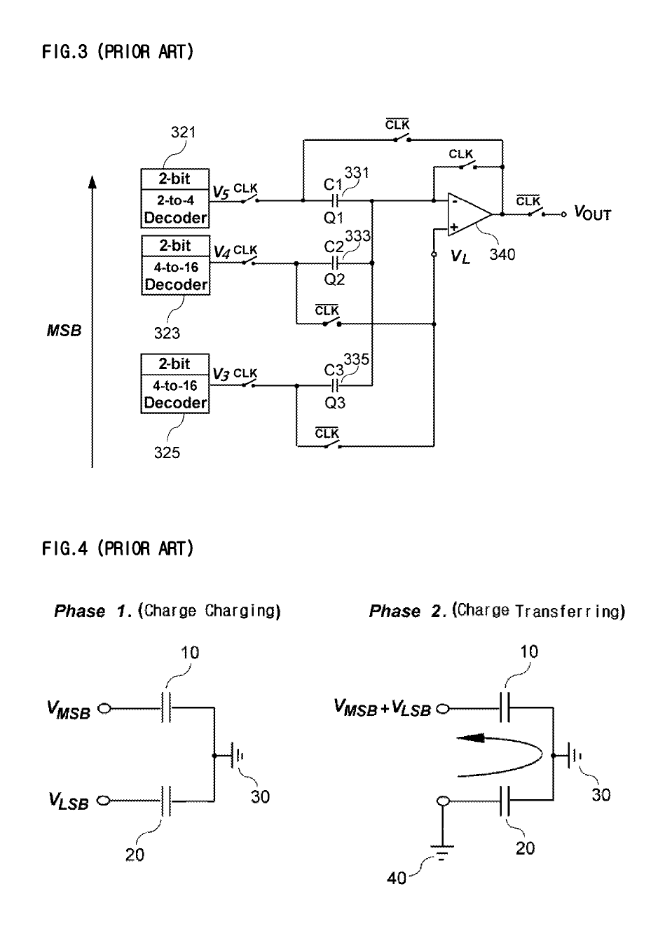

### DETAILED DESCRIPTION OF PREFERRED EMBODIMENTS

Reference will now be made in greater detail to a preferred embodiment of the invention, an example of which is illustrated in the accompanying drawings. Wherever possible, the same reference numerals will be used throughout the drawings and the description to refer to the same or like parts.

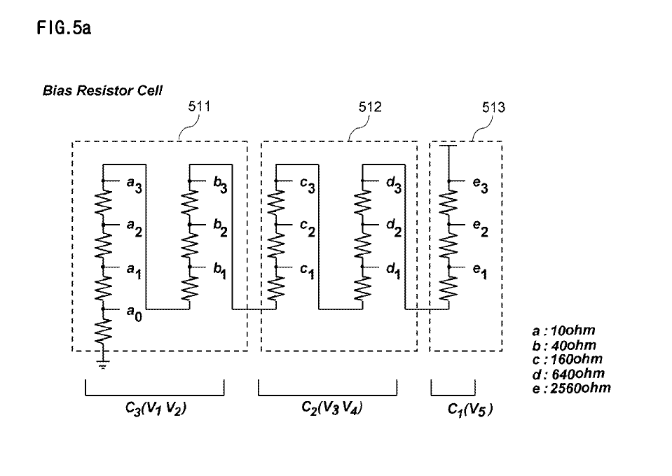

FIG. 5a shows resistor cells which constitute a DAC circuit for a 10-bit display in accordance with an embodiment of the present invention.

Referring to FIG. 5a, resistor cells, which constitute a DAC circuit in accordance with an embodiment of the present invention, are applied to 10 bits. The resistor cells include a first resistor cell 511, a second resistor cell 512, and a third resistor cell 513.

The first resistor cell 511 allows a first voltage V₁ or a second voltage V₂ outputted from respective decoders to be applied to a third capacitor C₃, through resistance dividing and switching operations. The first resistor cell 511 includes resistors with predetermined intervals defined between the resistors in the sequence of a0, a1, a2, a3, b1, b2 and b3 from a ground.

The second resistor cell 512 allows a third voltage V₃ or a fourth voltage V₄ outputted from respective decoders to be applied to a second capacitor C₂, through resistance dividing and switching operations. The second resistor cell 512 includes resistors with predetermined intervals defined between the resistors in the sequence of c1, c2, c3, d1, d2 and d3 after b3.

The third resistor cell 513 allows a fifth voltage V₅ outputted from a decoder to be applied to a first capacitor C₁, through resistance dividing and switching operations. The third resistor cell 513 includes resistors with predetermined intervals defined between the resistors in the sequence of e1, e2 and e3 after d3.

In the first resistor cell 511, the second resistor cell 512 and the third resistor cell 513, resistance values should be increased as the number of bits increases when implementing interpolation. In the embodiment of the present invention, each of a0, a1, a2 and a3 corresponds to 10 ohms, each of b1, b2 and b3 corresponds to 40 ohms, each of c1, c2 and c3 corresponds to 160 ohms, each of d1, d2 and d3 corresponds to 640 ohms, and each of e1, e2 and e3 corresponds to 2,560 ohms.

FIG. 5b shows a DAC circuit using a charge subtraction method according to the present invention.

Referring to FIG. 5b, a DAC circuit using a charge subtraction method according to the present invention is exemplified as a DAC for a 10-bit display. The DAC circuit includes a plurality of decoders 521, 523a, 523b, 525a and 525b, first, second and third capacitors 531, 533 and 535 for realizing charge charging by a charge subtraction method and charge transferring by a charge transfer interpolation method, and an operational amplifier 540. Hereafter, the decoders 521, 523a, 523b, 525a and 525b will be exemplified as 2-to-4 decoders.

The plurality of 2-to-4 decoders include first, second, third, fourth and fifth 2-to-4 decoders 521, 523a, 523b, 525a and 525b for processing 10-bit data by the unit of 2 bits.

The first 2-to-4 decoder 521 receives a divided voltage corresponding to most significant 2 bits among the total 10 bits, and transfers a fifth voltage V₅ to the first capacitor 531 through a switching operation.

Each of the second and third 2-to-4 decoders 523a and 523b receives a divided voltage corresponding to 2 bits among the remaining lower 8 bits, and transfers a fourth voltage V₄ or a third voltage V₃ to the second capacitor 533 through a switching operation.

Each of the fourth and fifth 2-to-4 decoders 525a and 525b receives a divided voltage corresponding to 2 bits among the remaining lower 4 bits, and transfers a second voltage V₂ or a first voltage V₁ to the third capacitor 535 through a switching operation.

The operational amplifier 540 receives through a + terminal a reference voltage V_{L} and receives through a − terminal an interpolation voltage corresponding to a total charge amount (Qs=Q1+Q2+Q3) after the charges stored in the respective third and second capacitors 535 and 533 are transferred to the first capacitor 531. The operational amplifier 540 compares the interpolation voltage with the reference voltage V_{L} and generates an output voltage Vout.

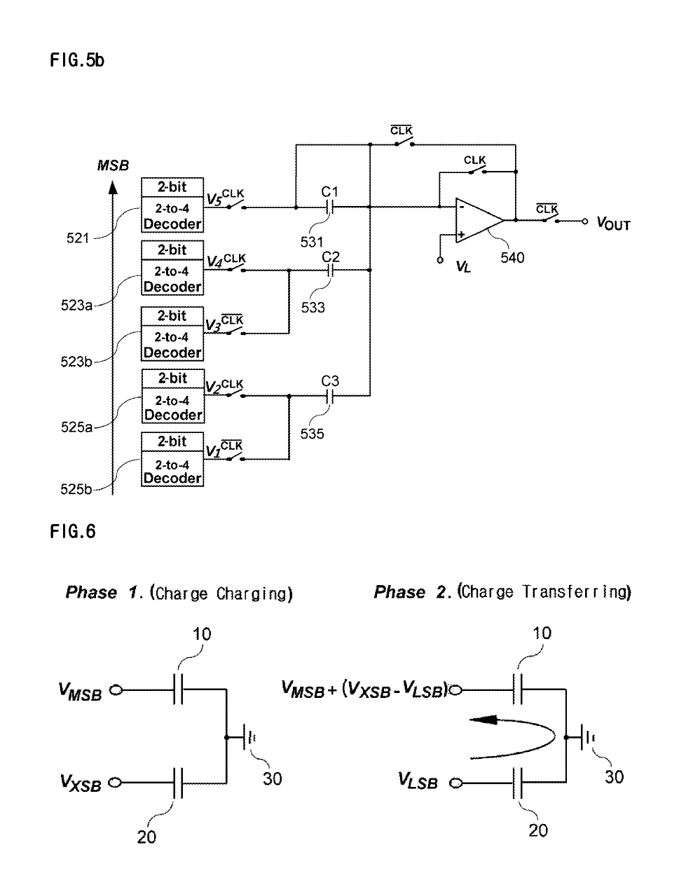

FIG. 6 is a diagram explaining a charge transfer interpolation method using a charge subtraction method according to the present invention.

Referring to FIG. 6, a phase 1 represents a charge charging step of storing charges in respective capacitors 10 and 20 by applying desired voltages. In the phase 1, the first capacitor 10 and the second capacitor 20 are connected with an AC ground part 30 in such a manner that a voltage V_{MSB} of a most significant bit is applied to the first capacitor 10 and a voltage V_{XSB} is applied to the second capacitor 20.

A phase 2 represents a charge transferring step of transferring the charges obtained by subtracting a desired interpolation value from the voltages stored in the first capacitor 10 and the second capacitor 20, to the first capacitor 10. In the phase 2, unlike the conventional art in which an AC ground voltage is applied to the second capacitor 20, a voltage V_{LSB} of a least significant bit is applied to the second capacitor 20, and the first capacitor 10 and the second capacitor 20 are connected with the AC ground part 30.

Hereafter, a charge transfer interpolation method using a charge subtraction method according to the present invention will be described simply.

First, in the case of the phase 1, an operation is performed to apply the value of the V_{MSB} to the first capacitor 10 and apply not the AC ground voltage as in the conventional art but the value of the V_{XSB} to the second capacitor 20. In the case of the phase 2, an operation is performed to apply the value of the V_{LSB} to the second capacitor 20. Here, the V_{MSB}, V_{XSB} and V_{LSB} represent optional voltages which satisfy V_{MSB}>V_{XSB}>V_{LSB}.

If the operations of the phase 1 and the phase 2 are completed, not the entire charge amount C*V_{LSB} stored in the second capacitor 20 in the conventional art but a subtracted charge amount of C*(V_{XSB}−V_{LSB}) is transferred to the first capacitor 10.

The operational amplifier 540 receives a voltage V_{XSB}−V_{LSB} corresponding to the charge amount of C*(V_{XSB}−V_{LSB}) and generates the final output voltage Vout of V_{MSB}+(V_{XSB}−V_{LSB}).

Hereinbelow, an operational principle of a DAC circuit for realizing the charge transfer interpolation method using a charge subtraction method according to the present invention will be described in detail with reference to FIGS. 5b and 6.

In the case of the phase 1, when assuming that charges stored in the first, second and third capacitors 531, 533 and 535 are Q1, Q2 and Q3, respectively, a total stored charge amount that satisfies Qs=Q1+Q2+Q3 is expressed as in the following Mathematical Equation 6 by the formula Q=CV.

Qs=C₁(V₅−V_{L}−V_{OS})+C₂(V₄−V_{L}−V_{OS})+C₃(V₂−V_{L}−V_{OS}) [Mathematical Equation 6]

Here, V_{OS} means an offset voltage which is generated from the operational amplifier 540.

In the case of the phase 2, after all the charges stored in the respective second and third capacitors 533 and 535 are transferred to the first capacitor 531, the final output voltage Vout is generated. When assuming that the amounts of charges transferred to the first, second and third capacitors 531, 533 and 535 are Q1, Q2 and Q3, respectively, a total amount of transferred charges satisfies a formula Qt=Q1+Q2+Q3 and is expressed as in the following Mathematical Equation 7 by the formula Q=CV.

Qt=C₁(Vout−V_{L}−V_{OS})+C₂(V₃−V_{L}−V_{OS})+C₃(V₁−V_{L}−V_{OS}) [Mathematical Equation 7]

Here, V_{OS} means an offset voltage which is generated from the operational amplifier 540.

Meanwhile, since the electric charge conservation law satisfies Qs=Qt, the total output voltage Vout is expressed as in the following Mathematical Equation 8.

$$Vout = {V}_{5} + \frac{{C}_{2}}{{C}_{1}} ( {V}_{4} - {V}_{L} ) + \frac{{C}_{3}}{{C}_{1}} ( {V}_{2} - {V}_{1} ) \qquad [ Mathematical Equation 8 ]$$

When assuming that digital code values corresponding to V₅, V₄, V₃, V₂ and V₁ are D₁, D₂, D₃, D₄ and D₅, respectively, and a supply voltage necessary for the DAC is V_{DD}, V₅, V₉, V₃, V₂ and V₁ are expressed by respective equations given in the following Mathematical Equation 9.

$${V}_{5} = \frac{{V}_{DD}}{{2}^{2}} {D}_{1} \\ {V}_{4} = \frac{{V}_{DD}}{{2}^{2} \times {2}^{2}} {D}_{2} \\ {V}_{3} = \frac{{V}_{DD}}{{2}^{2} \times {2}^{2} \times {2}^{2}} {D}_{3} \\ {V}_{2} = \frac{{V}_{DD}}{{2}^{2} \times {2}^{2} \times {2}^{2} \times {2}^{2}} {D}_{4} \\ {V}_{1} = \frac{{V}_{DD}}{{2}^{2} \times {2}^{2} \times {2}^{2} \times {2}^{2} \times {2}^{2}} {D}_{5} \qquad [ Mathematical Equation 9 ]$$

When C1=C2=C3, the total output voltage is simply expressed in the form of Vout=V₅+(V₄−V₃)+(V₂−V₁). When substituting the Mathematical Equation 9 for the Mathematical Equation 8 and simplifying the Mathematical Equation 8, the total output voltage Vout is expressed as in the following Mathematical Equation 10.

$$Vout = \frac{{V}_{DD}}{{2}^{2}} {D}_{1} + ( \frac{{V}_{DD}}{{2}^{2} \times {2}^{2}} {D}_{2} - \frac{{V}_{DD}}{{2}^{2} \times {2}^{2} \times {2}^{2}} {D}_{3} ) + ( \frac{{V}_{DD}}{{2}^{2} \times {2}^{2} \times {2}^{2} \times {2}^{2}} {D}_{4} - \frac{{V}_{DD}}{{2}^{2} \times {2}^{2} \times {2}^{2} \times {2}^{2} \times {2}^{2}} {D}_{5} ) \qquad [ Mathematical Equation 10 ]$$

Through the Mathematical Equation 10, the characterizing features of the present invention can be summarized as follows.

First, the final output voltage Vout given in the left side is expressed by the second term V₄−V₃ of the Mathematical Equation 10 as a result of applying the charge subtraction method to the second capacitor 533 and is similarly expressed by the third term V₂−V₁ of the Mathematical Equation 10 as a result of applying the charge subtraction method to the third capacitor 535.

Second, the second and third capacitors 533 and 535 do not store desired values at a time by being applied with the conventional interpolation method, but are applied one more time with an additional interpolation method. As a result, not the entire charge amount C*V_{LSB} as in the conventional art but the charge amount of C*(V_{XSB}−V_{LSB}) corresponding to a difference between the voltage V_{XSB} applied in the phase 1 and the voltage V_{LSB} applied in the second phase 2 is transferred to the first capacitor 531.

This corresponds to the fact that the first 4-bit decoder 323 and the second 4-bit decoder 325 in the conventional art are changed in their configurations to respectively have two pairs of 2-bit decoders, that is, the second and third 2-to-4 decoders 523a and 523b and the fourth and fifth 2-to-4 decoders 525a and 525b, and means that interpolation is applied substantially one more time for each capacitor. This may be confirmed through the expression of the second term V₄−V₃ of the Mathematical Equation 10 and the expression of the third term V₂−V₁ of the Mathematical Equation 10.

Third, in order to apply a charge subtraction method or a charge summation method to the DAC circuit according to the present invention, new digitally coded D₁, D₂, D₃, D₄ and D₅ should be applied.

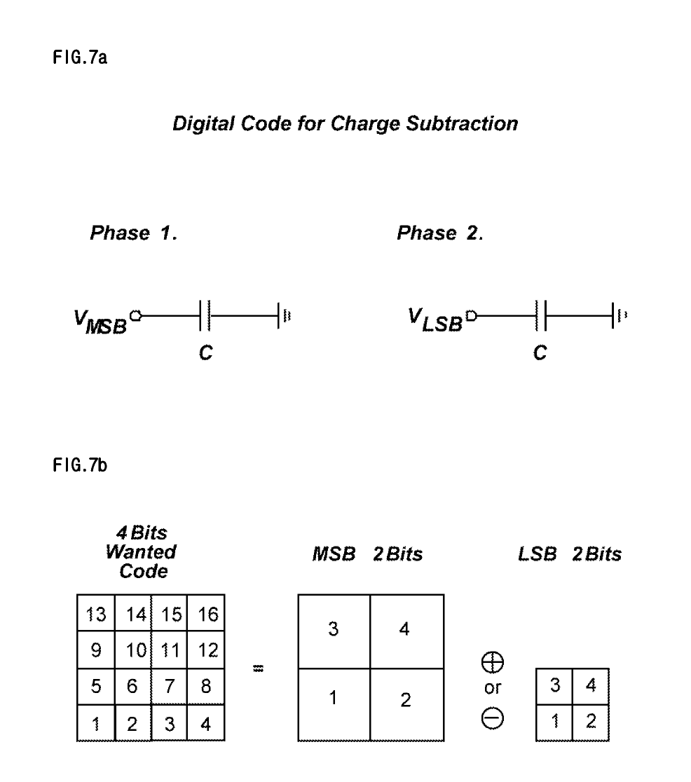

FIG. 7a is a diagram showing allocation of digital codes to a phase 1 and a phase 2 to allow a charge subtraction method or a charge summation method to be used according to the present invention.

Referring to FIG. 7a, in the present invention, in order to apply a charge subtraction method or a charge summation method to a DAC circuit, an MSB code operation corresponding to the V_{MSB} is performed in the case of the charge charging step of the phase 1, and an LSB code operation corresponding to the V_{LSB} is performed in the case of the charge transferring step of the phase 2, so that the same voltage values as the V_{MSB} and V_{LSB} in the conventional art can be obtained.

FIG. 7b shows an example of realizing an MSB code operation and an LSB code operation by applying the charge subtraction method or the charge summation method according to the present invention to a 4-bit decoder.

Referring to FIG. 7b, in the case of 4-bit decoder, 2⁴ code blocks 1, 2, . . . and 16 exist. In the case of MSB 2 bits, 2² code blocks 1, 2, 3 and 4 exist. In the case of LSB 2 bits, 2² code blocks 1, 2, 3 and 4 exist. Charges are charged in correspondence to the sizes of the code blocks.

In the case of the MSB 2 bits, the code block 1 corresponds to the code blocks 1, 2, 5 and 6 of the 4-bit decoder and has a size acquired by combining these four code blocks. Similarly, the code blocks 2, 3 and 4 of the MSB 2 bits correspond to the code blocks 3, 4, 7 and 8, the code blocks 9, 10, 13 and 14, and the code blocks 11, 12, 15 and 16, respectively, and have sizes acquired by combining these respective four code blocks.

In the case of the LSB 2 bits, the size of the code blocks 1, 2, 3 and 4 is the same as the size of the code blocks 1, 2, . . . and 16 of the 4-bit decoder.

Table 1 shows the values of MSB codes and LSB codes when the charge subtraction method according to the present invention is applied to the 4-bit decoder.

TABLE 1

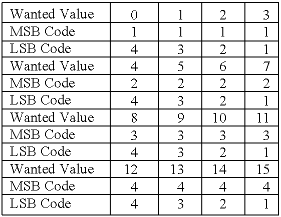

Table 2 shows the values of MSB codes and LSB codes when the charge summation method according to the present invention is applied to the 4-bit decoder.

TABLE 2

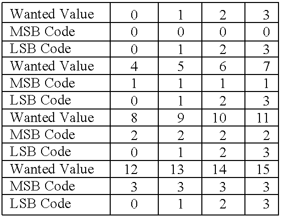

Referring to FIG. 7b, Table 1 and Table 2, in the case of 4 bits, code blocks 1, 2, . . . and 9 colored with the heavy color represent a state in which charges are charged. This is realized by applying the charge subtraction method or the charge summation method to the MSB code blocks 1 and 2 colored with the heavy color and the LSB code block 1 colored with the light color.

That is to say, the code value of 9 can be realized by subtracting the code value 3 of the LSB 2 bits from the code value 3 of the MSB 2 bits in Table 1 when using the charge subtraction method, and can be realized by summating the code value 2 of the MSB 2 bits and the code value 1 of the LSB 2 bits in Table 2 when using the charge summation method.

As is apparent from the above description, in the present invention, since the number of decoders can be decreased to one half when compared to the conventional interpolation method, advantages are provided in that not only the overall size of a DAC can be reduced to one half but also it is possible to eliminate the . offset voltage of an operational amplifier.

Although a preferred embodiment of the present invention has been described for illustrative purposes, those skilled in the art will appreciate that various modifications, additions and substitutions are possible, without departing from the scope and the spirit of the invention as disclosed in the accompanying claims.

What is claimed is:

1. A DAC circuit using a charge subtraction method and a change transfer interpolation method, comprising:
resistor cells configured to divide a voltage of data of total K bits (=upper M bits+lower N bits) by respective resistance dividers;
a decoder group configured to receive digital data of the M bits and the N bits divided in the resistor cells, process the digital data by the unit of X bits, and output respective corresponding voltages;
a capacitor group configured to receive the voltages outputted from the decoder group and realize charge charging by a charge subtraction method and charge transferring by a charge transfer interpolation method; and
an operational amplifier having a first input terminal which receives a reference voltage and a second input terminal which receives an interpolation voltage corresponding to an amount of charges transferred from the capacitor group, and configured to generate an output voltage.

2. The DAC circuit according to claim 1, wherein the unit of X bits includes the unit of 2 bits.

3. The DAC circuit according to claim 1, wherein the decoder group includes a 2-to-4 decoder group.

4. The DAC circuit according to claim 1, wherein the resistor cells comprise:
a first resistor cell configured to divide a first voltage and a second voltage and apply the first voltage and the second voltage to fourth and fifth decoders;
a second resistor cell configured to divide a third voltage and a fourth voltage and apply the third voltage and the fourth voltage to second and third decoders; and
a third resistor cell configured to divide a fifth voltage and apply the fifth voltage to a first decoder.

5. The DAC circuit according to claim 1, wherein, when the K bits are 10 bits, the decoder group comprises:
a first decoder configured to receive a divided voltage corresponding to when the M bits are 2 bits and apply the fifth voltage to a first capacitor of the capacitor group through a switching operation;
second and third decoders configured to receive divided voltages each corresponding to 2 bits among the lower 8 bits (N=8) and apply the fourth voltage and the third voltage to a second capacitor of the capacitor group through a switching operation; and
fourth and fifth decoders configured to receive divided voltages each corresponding to 2 bits among the lower 4 bits (N=4) and apply the second voltage and the first voltage to a third capacitor of the capacitor group through a switching operation.

6. The DAC circuit according to claim 3, wherein, when an inequality V_{MSB}>V_{XSB}>V_{LSB} is satisfied, the charge charging by the charge subtraction method is implemented by applying a V_{MSB} voltage to the first capacitor and applying a V_{XSB} voltage to the second capacitor and the third capacitor, and the charge transferring by the charge transfer interpolation method is implemented by applying a V_{LSB} voltage to the second capacitor and the third capacitor so that an amount of charges corresponding to a subtracted voltage of V_{XSB}−V_{LSB} is transferred to the first capacitor.

7. The DAC circuit according to claim 4, wherein, when assuming that digital code values corresponding to the fifth, fourth, third, second and first voltages V₅, V₄, V₃, V₂ and V₁ are D₁, D₂, D₃, D₄ and D₅, respectively, and a supply voltage necessary for the DAC circuit is V_{DD}, the output voltage Vout is expressed as in the following mathematical equation:
$$Vout = \frac{{V}_{DD}}{{2}^{2}} {D}_{1} + ( \frac{{V}_{DD}}{{2}^{2} \times {2}^{2}} {D}_{2} - \frac{{V}_{DD}}{{2}^{2} \times {2}^{2} \times {2}^{2}} {D}_{3} ) + ( \frac{{V}_{DD}}{{2}^{2} \times {2}^{2} \times {2}^{2} \times {2}^{2}} {D}_{4} - \frac{{V}_{DD}}{{2}^{2} \times {2}^{2} \times {2}^{2} \times {2}^{2} \times {2}^{2}} {D}_{5} )$$

8. The DAC circuit according to claim 5, wherein the digital code values are generated through an MSB code operation corresponding to the V_{MSB} voltage and an LSB code operation corresponding to the V_{LSB} voltage.

9. The DAC circuit according to claim 6, wherein, in the charge charging by the charge subtraction method, an amount of charges corresponding to a value obtained by subtracting an LSB code value from an MSB code value is charged.
